(19) United States
(12) Patent Application Publication
(10) Pub. No.: US 2009/0283917 A1
(43) Pub. Date: Nov. 19, 2009

(54) SYSTEMS AND METHODS FOR VERTICAL STACKED SEMICONDUCTOR DEVICES

(75) Inventors: Lianzhong Yu, Redmond, WA (US); Steve Chang, Redmond, WA (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: Honeywell International Inc., Morristown, NJ (US)

(21) Appl. No.: 12/123,127

(22) Filed: May 19, 2008

(51) Int. Cl. H01L 23/52; H01L 21/00

(52) U.S. Cl. 257/777; 438/109; 257/E23.141; 257/E21.001

(57) ABSTRACT

Systems and methods fabricate a vertically stacked multi-chip semiconductor device assembly. An exemplary assembly is fabricated by forming a first semiconductor device in a first semiconductor device layer with a first connector located at a first surface of the first semiconductor device layer; forming a second semiconductor device in a second semiconductor device layer with a second connector located at an interior surface of the second semiconductor device layer; forming a via in the first semiconductor device layer extending from the first surface to an opposing second surface of the first semiconductor device layer corresponding to the location of the second connector; and joining the second surface of the first semiconductor device layer and the interior surface of the second semiconductor device layer, wherein the via at the second surface of the first semiconductor device layer is coupled to the second connector of the second semiconductor device.

### BACKGROUND OF THE INVENTION

As semiconductor devices become increasingly smaller, the devices in which the semiconductor devices are used are also becoming smaller. Accordingly, it has become more important to decrease the overall packaging size of the semiconductor devices.

In many applications, a plurality of semiconductor devices, acting in cooperation with each other, are are packaged together as a multi-chip semiconductor device assembly. For example, an accelerometer device may employ three orthogonally oriented Micro-Electro-Mechanical Systems (MEMs) accelerometers to determine acceleration of the device. A gyroscope may similarly employ a plurality of MEMs gyroscopes to determine angular rotation of the device. The three accelerometers and/or three gyroscopes may be packaged into a single, and relatively small, accelerometer and/or gyroscope device, or a combination thereof.

Further, in some applications it is very desirable to precisely align and/or orient individual semiconductor devices relative to each other. For example, precise alignment and orientation of three orthogonally oriented gyroscope silicon devices during fabrication of a gyroscope system is very desirable to more accurately sense three-dimensional rotational movement of the device.

One significant problem faced when combining a plurality of silicon devices into a multi-chip semiconductor device assembly is providing electrical access to the individual silicon devices. One solution is to provide separate interconnections to the individual silicon devices of the multi-chip semiconductor device assembly. For example, one system uses a redistribution bond pad, as disclosed in in U.S. Pat. Application Publication No. 2003/0203537 to Koopmans, entitled “METHOD OF FABRICATING STACKED DIE CONFIGURATIONS UTILIZING REDISTRIBUTION BOND PADS,” filed on Apr. 24, 2003. Here, individual semiconductor devices are offset from each other and/or are separated by spacers. The individual semiconductor devices may then be individually connected to the redistribution bond pad to provide connector access to the outside of the package. However, individual electrical contacts to each electrical connector point on the semiconductor devices are required, thus making the process of establishing the electrical connections relatively complex.

Another solution is to sequentially fabricate individual semiconductors devices on top of each other to form a single multi-chip semiconductor device assembly. Connectors may then be built alongside the semiconductor devices in a coordinated fashion. For example, U.S. Pat. No. 7,326,629 to Nagarajan et al., entitled “METHOD OF STACKING SUBSTRATES BY TRANSFER BONDING,” describes a method of building a stack of semiconductor devices using a relatively complex fabrication process. However, building semiconductor devices on top of each other in a layer-by-layer serial fashion requires a relatively lengthy and complex fabrication process.

Accordingly, it is desirable to simplify the complexity of fabricating a single multi-chip semiconductor device assembly. Further, it is desirable to more precisely align and orient the individual semiconductor devices with each other in a single multi-chip semiconductor device assembly.

### SUMMARY OF THE INVENTION

Systems and methods of fabricating a multi-chip semiconductor device assembly are disclosed. An exemplary embodiment forms a first semiconductor device in a first semiconductor device layer, the first semiconductor device formed with at least one first connector located at a first surface of the first semiconductor device layer; forms a second semiconductor device in a second semiconductor device layer, the second semiconductor device formed with at least one second connector located at an interior surface of the second semiconductor device layer; forms a via in the first semiconductor device layer, the via extending from the first surface of the first semiconductor device layer to an opposing second surface of the first semiconductor device layer, and the via at the second surface of the first semiconductor device layer corresponding to the location of the second connector of the second semiconductor device; and joins the second surface of the first semiconductor device layer and the interior surface of the second semiconductor device layer, wherein the via at the second surface of the first semiconductor device layer is coupled to the second connector of the second semiconductor device.

### BRIEF DESCRIPTION OF THE DRAWINGS

Preferred and alternative embodiments are described in detail below with reference to the following drawings:

FIG. 1 is a conceptual cross sectional view of a first semiconductor device layer, a second semiconductor device layer, and a semiconductor cover layer used to fabricate embodiments of a single multi-chip semiconductor device assembly;

FIG. 2 is a conceptual cross sectional view of the first semiconductor device layer, the second semiconductor device layer, and the semiconductor cover layer during exemplary stages of fabricating the single multi-chip semiconductor device assemblies;

FIG. 3 is a conceptual cross sectional view of the first semiconductor device layer, the second semiconductor device layer, and the semiconductor cover layer during later exemplary stages of fabricating the single multi-chip semiconductor device assemblies;

FIG. 4 illustrates the second surface of the first semiconductor device layer joined with the interior surface of the second semiconductor device layer; and

FIG. 5 is a conceptual illustration of a plurality of multi-chip semiconductor device assemblies after dicing of the joined first semiconductor device layer, second semiconductor device layer, and semiconductor cover layer.

### DETAILED DESCRIPTION OF THE PREFERRED EMBODIMENT

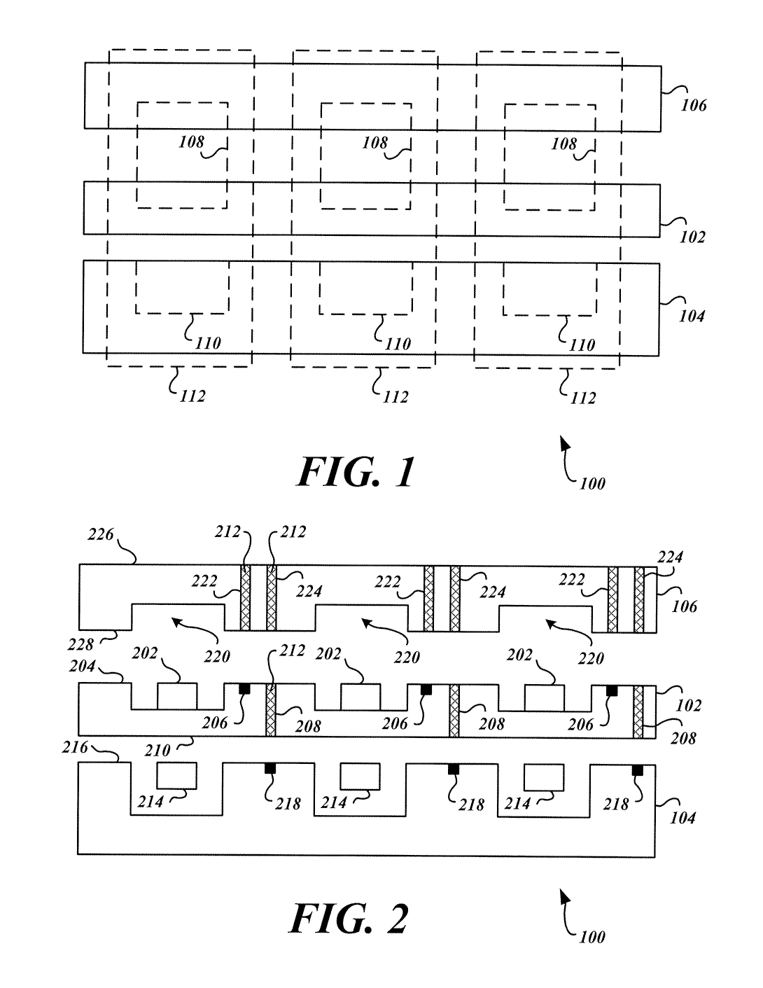

FIG. 1 is a conceptual cross sectional view of a first semiconductor device layer 102, a second semiconductor device layer 104, and a semiconductor cover layer 106 used to fabricate embodiments of a multi-chip semiconductor device assembly 100. In region 108, a first semiconductor device will be fabricated at some stage in the fabrication process. At another stage in the fabrication process, the first semiconductor device layer 102 will be joined with the semiconductor cover layer 106. In region 110, a second semiconductor device will be fabricated at another stage in the fabrication process. At yet another stage in the fabrication process, the first semiconductor device layer 102 will be joined with the second semiconductor device layer 104. Joining is effected using any suitable bonding process or the like which joins the semiconductor device layers 102, 104, and/or 106, and the devices and components thereof. Any suitable bonding technology may be employed, such as, but not limited to, silicon-silicon fusion bonding, silicon Au eutectic bonding, thermal compression bonding, anodic bonding, or glass frit bonding.

After the joining of the completed first semiconductor device layer 102, the second semiconductor device layer 104, and the semiconductor cover layer 106, a plurality of individual single multi-chip semiconductor device assemblies will be diced from the regions 112. Any suitable alignment means may be used during the joining of the semiconductor device layers 102 and 104 to achieve a highly accurate vertical alignment of the fabricated semiconductor devices. A significant and unexpected benefit of the fabrication process that joins the semiconductor device layers 102, 104, and/or 106 is that the bonding is performed at the wafer level or at a level where bonding is performed on relatively large portions of a wafer. That is, the semiconductor device layers 102, 104, and/or 106 are joined when at at the wafer level, or substantially at a wafer level, during bonding. Thus, vertical stacks of semiconductors are fabricated as the wafers having the semiconductor device layers 102, 104, and/or 106 thereon are joined.

FIG. 2 is a conceptual cross sectional view of the first semiconductor device layer 102, the second semiconductor device layer 104, and the semiconductor cover layer 106 during exemplary stages of fabricating the single multi-chip semiconductor device assemblies 100. It is appreciated that the fabrication processes are conceptually described to the extent necessary to describe novel features employed by embodiments of the multi-chip semiconductor device assembly 100. Thus, several stages of fabrication are required to fabricate the first semiconductor device layer 102, the second semiconductor device layer 104, and the semiconductor cover layer 106 described below. The various individual stages of fabrication may be carried out separately, at different times, at different locations, and/or with different fabrication devices. The first semiconductor device layer 102, the second semiconductor device layer 104, and the semiconductor cover layer 106 are described together in FIG. 2 to facilitate a conceptual understanding by one skilled in the art of semiconductor device fabrication.

The first semiconductor device layer 102, after several stages of fabrication, has a plurality of first semiconductor devices 202 formed on or near a first surface 204. Each first semiconductor device 202 has at least one connector 206 on or near the first surface 204 to provide electrical or optical connectivity to its respective first semiconductor device 202. It is appreciated that the first semiconductor devices 202 may have a plurality of other connectors (not shown). The first semiconductor devices 202, and their associated connectors 206, may be fabricated using any suitable process, such as, but not limited to, etching or micromachining. Further, several stages may be required to fabricate the first semiconductor devices 202 and their associated connectors 206. The individual fabrication stages are not described herein for brevity. For example, several fabrication stages would be required to form Micro-Electro-Mechanical Systems (MEMs) accelerometers or MEMs gyroscopes (the first semiconductor devices 202).

A plurality of vias 208 are formed in the first semiconductor device layer 102. The vias 208 may be formed by any suitable etching or micromachining process, such as, but not limited to, deep reactive ion etching (DRIE). The vias 208 provide electrical connectivity through the first semiconductor device layer 102. The vias 208 extend from the first surface 204 to a second surface 210 of the first semiconductor device layer 102.

It is appreciated that the vias 208 providing electrical or optical connectivity through the first semiconductor device layer 102 are only conceptually described for brevity. One skilled in the art appreciates the various fabrication steps associated with forming the vias 208 so that they are conductive. For example, but not limited to, fabrication of one exemplary type of the via 208 includes oxidation of the walls of the via 208 to form an electrically insulating barrier, followed by filling of the via 208 with an electrically conductive polysilicon fill 212. In other applications, an optical insulator barrier and an optically conductive fill material could be used in the vias 208.

The second semiconductor device layer 104, after several stages of fabrication, has a plurality of second semiconductor devices 214 formed on or near an interior surface 216. Each second semiconductor device 214 has at least one connector 218 on or near the interior surface 216 to provide electrical or optical connectivity to its respective second semiconductor device 214. It is appreciated that the second semiconductor devices 214 may have a plurality of other connectors (not shown). The second semiconductor devices 214, and their associated connectors 218, may be formed using any suitable process, such as, but not limited to, etching or micromachining. Further, several stages may be required to fabricate the second semiconductor devices 214 and their associated connectors 218. The individual fabrication stages are not described herein for brevity.

For example, the second semiconductor devices 214 may also be MEMs accelerometers and/or MEMs gyroscopes. Here, the second semiconductor devices 214 are shown as being undercut, and thus separated from, the second semiconductor device layer 104 (but anchored by a suitable means not shown in FIG. 2 for brevity).

In some applications, such as with MEMs accelerometers and/or MEMs gyroscopes, an optional free space region 220 may be formed in the semiconductor cover layer 106 above the first semiconductor devices 202. The regions 220 may be formed using any suitable process, such as, but not limited to, etching or micromachining, which are not described herein for brevity.

A plurality of second vias 222 and a plurality of third vias 224 are formed in the semiconductor cover layer 106. The vias 222, 224 may be formed by any suitable etching or micromachining process, such as, but not limited to, deep reactive ion etching (DRIE). The vias 222, 224 provide electrical connectivity through the semiconductor cover layer 106. The vias 222, 224 extend from an exterior surface 226 to an interior surface 228 of the semiconductor cover layer 106.

It is appreciated that the vias 222, 224 providing electrical or optical connectivity through the first semiconductor device layer 102, are only conceptually described for brevity. One skilled in the art appreciates the various fabrication steps associated with forming the vias 208 so that they are conductive. For example, but not limited to, fabrication of one exemplary type of the vias 222, 224 includes oxidation of the walls of the vias 222, 224 to form an insulating barrier, followed by filling of the vias 222, 224 with an electrically conductive polysilicon fill 212 to provide electrical connectivity. In other applications, an optical insulator barrier and an optically conductive fill material could be used in the vias 222, 224.

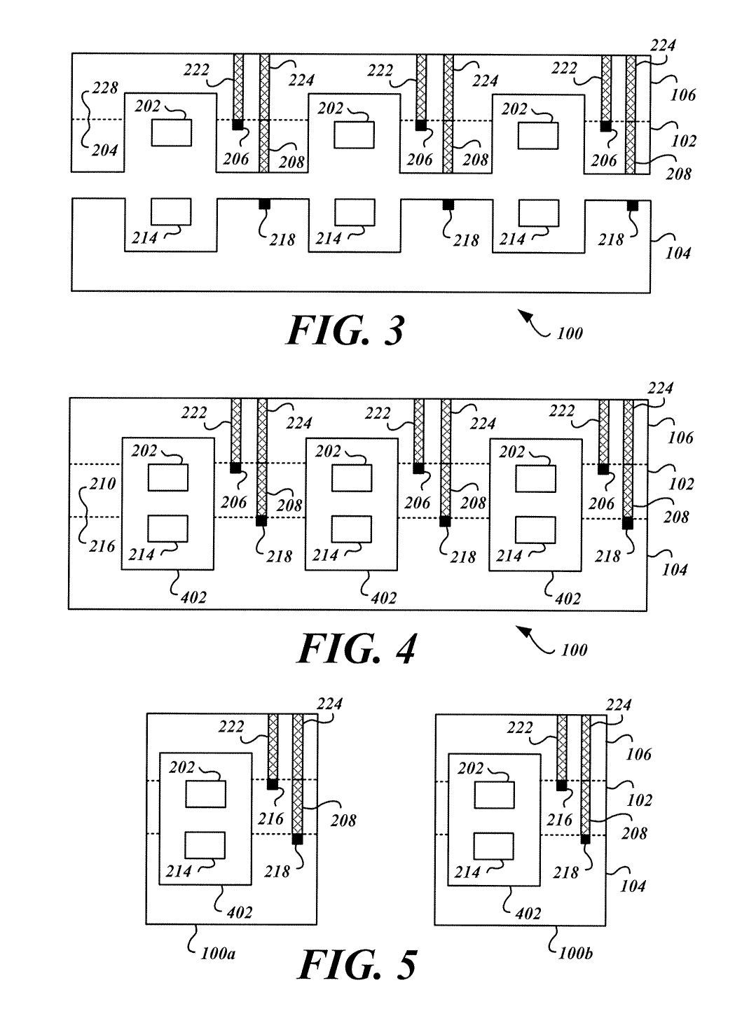

FIG. 3 is a conceptual cross sectional view of the first semiconductor device layer 102, the second semiconductor device layer 104, and the semiconductor cover layer 106 during later exemplary stages of fabricating the single multi-chip semiconductor device assemblies 100. Here, the first semiconductor device layer 102 has been joined with the semiconductor cover layer 106. Thus, the semiconductor device layer and the semiconductor cover layer 106 are joined when at at the wafer level, or substantially at a wafer level, during bonding.

It is appreciated by one skilled in the art that the layout of the first semiconductor devices 202, and their associated connectors 206, on the first semiconductor device layer 102 has been precisely predefined prior to fabrication. Similarly, the layout of the second semiconductor devices 214, and their associated connectors 218, on the second semiconductor device layer 104 has been precisely predefined prior to fabrication. The fabrication processes precisely locate the semiconductor devices 202, 214, and their associated connectors 206, 218, respectively, in their respective predefined locations by using a masking system to control the various etching and/or micromachining processes. More particularly, the precise locations of the connectors 206 on the first semiconductor device layer 102 and the precise locations of the connectors 218 on the second semiconductor device layer 104 are known.

Accordingly, the first vias 208 formed in the first semiconductor device layer 102 may be precisely located based upon the known location of the connectors 218 on the second semiconductor device layer 104. Similarly, the second vias 222 formed in the semiconductor cover layer 106 may be precisely located based upon the known location of the connectors 206 on the first semiconductor device layer 102. Further, the third vias 224 formed in the semiconductor cover layer 106 may be precisely located based upon the known location of the first vias 208 on the first semiconductor device layer 102 and based on the connectors 218 on the second semiconductor device layer 104.

As noted above, FIG. 3 illustrates the first surface 204 of the first semiconductor device layer 102 joined with the interior surface 228 of the semiconductor cover layer 106. Since the second vias 222 are precisely formed in a known location, and are configured to correspond the known location of the connectors 206 on the first semiconductor device layer 102, each of the second vias 222 become communicatively coupled to the respective connector 206 upon the joining of the first semiconductor device layer 102 with the semiconductor cover layer 106. Similarly, since third vias 224 are precisely formed in a known location configured to correspond the known location of the first vias 208 on the first semiconductor device layer 102, each of the third vias 224 become communicatively coupled to the respective first via 208 upon the joining of the first semiconductor device layer 102 with the semiconductor cover layer 106.

FIG. 4 illustrates the second surface 210 of the first semiconductor device layer 102 joined with the interior surface 216 of the second semiconductor device layer 104. Since the first vias 208 are precisely formed in a known location configured to correspond the known location of the connectors 218 on the second semiconductor device layer 104, each of the first vias 208 become communicatively coupled to the respective connector 218 upon the joining of the first semiconductor device layer 102 with the second semiconductor device layer 104. Thus, the semiconductor devices 202, 214 are vertically stacked with each other in the regions 402.

The joining of the first semiconductor device layer 102, the second semiconductor device layer 104, and the semiconductor cover layer 106 requires precise alignment of the layers 102, 104, 106. Any suitable alignment means and/or method may be used for joining the first semiconductor device layer 102, the second semiconductor device layer 104, and the semiconductor cover layer 106. For brevity, such alignment means and/or methods are not described. It is appreciated that the semiconductor device layers 102, 104, and/or 106 may be joined when at at the wafer level, or substantially at a wafer level, during bonding. Thus, vertical stacks of semiconductors are fabricated as the wafers having the semiconductor device layers 102, 104, and/or 106 thereon are joined.

FIG. 5 is a conceptual illustration of a plurality of multi-chip semiconductor device assemblies 100a, 100b after dicing of the joined first semiconductor device layer 102, second semiconductor device layer 104, and semiconductor cover layer 106. It is appreciated that a very large number of multi-chip semiconductor device assemblies 100i are made from the joined first semiconductor device layer 102, the second semiconductor device layer 104, and the semiconductor cover layer 106.

After final packaging, a signal may be communicated between one of the second semiconductor devices 214 and the exterior surface 226 of the semiconductor cover layer 106, wherein the signal is communicated through the corresponding via 222. Similarly, a signal may be communicated between one of the second semiconductor devices 214 and the exterior surface 226 of the semiconductor cover layer 106, wherein the signal is communicated through the corresponding vias 208, 224. Depending upon the embodiment, the signals may be electrical or optical.

In an exemplary embodiment, the semiconductor devices 202, 214 may be MEMs accelerometers or MEMs gyroscopes residing in regions 402. Since the first semiconductor device layer 102, the second semiconductor device layer 104, and the semiconductor cover layer 106 are aligned and then joined in a very precise manner, the vias 208, 222, 224, and the connectors 206, 218 are aligned and joined so as to become communicatively coupled. Thus, it is appreciated that the semiconductor devices 202, 214 are vertically stacked in a very precise manner so as to be precisely aligned with each other. Further, the semiconductor devices 202, 214 are precisely spaced in relation to each other. Accordingly, the interactions of the semiconductor devices 202, 214 with each other may be controllable. For example, noise and/or interference caused by the proximity of the semiconductor devices 202, 214 to each other may be mitigated by selective design and the precise fabrication processes.

As a nonlimiting illustrative example, the first semiconductor device 202 may be a first MEMs accelerometer oriented in a first direction to sense acceleration in a first direction. The second semiconductor device 214 may be a second MEMs accelerometer oriented in a second direction to sense acceleration in a second direction, wherein the second direction is perpendicular to the first direction.

Some embodiments of the multi-chip semiconductor device assemblies 100 provide the unexpected ability to join the vias 208, 222, 224, and the connectors 206, 218, without intervening connecting pads or the like. Because the first semiconductor device layer 102, the second semiconductor device layer 104, and the semiconductor cover layer 106 are precisely aligned upon the joining, the vias 208, 222, 224, and the connectors 206, 218 are aligned upon the joining such that connectivity is provided. In some embodiments, a current applied through the vias 208, 222, 224, and/or the connectors 206, 218, or a charge applied across the vias 208, 222, 224, and/or the connectors 206, 218, may be used to improve the connectivity of the vias 208, 222, 224, and/or the connectors 206, 218.

Another unexpected benefit of the multi-chip semiconductor device assemblies 100 is that the connectivity to the semiconductor devices 202, 214 is greatly simplified because the vias 222, 224 are available at the exterior surface 226 of the semiconductor cover layer 106. During packaging of a diced multi-chip semiconductor device assembly 100, connections to the vias 222, 224 may be made at the exterior surface 226. The availability of the vias 222, 224 at the exterior surface 226 significantly simplifies the connection geographies when the multi-chip semiconductor device assembly 100 is packaged. That is, connectivity to the semiconductor devices 202, 214 is available along the two dimensional plane of the exterior surface 226.

The above-described embodiments employed pre-formed vias extending from the exterior surface 226 of the semiconductor cover layer 106 to the connections 206, 218 of the semiconductor devices 202, 214, respectively, which were formed on different semiconductor device layers 102, 104, respectively. Other embodiments may use similarly fabricated vias to provide connectivity to semiconductor devices formed in further semiconductor device layers. For example, another via could be formed through the first semiconductor device layer 102 and the second semiconductor device layer 104 to provide connectivity to a contact of a third semiconductor device formed in a third semiconductor device layer (that has been joined with the second semiconductor device layer 104 or another intervening layer). Further, any number of vias may be formed to extend through many semiconductor device layers, or other material layers, to provided connectivity to semiconductor devices on the other semiconductor layers.

One skilled in the art appreciates that the second semiconductor devices 214 do not need to be the same type of semiconductor device as the first semiconductor devices 202. Further, the first semiconductor devices 202 on the first semiconductor device layer 102 may be different from each other. Similarly, the second semiconductor devices 214 on the second semiconductor device layer 104 may also be different from each other.

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

The embodiments of the invention in which an exclusive property or privilege is claimed are defined as follows:

1. A method for fabricating a multi-chip semiconductor device assembly, comprising:
forming a first semiconductor device in a first semiconductor device layer, the first semiconductor device formed with at least one first connector located at a first surface of the first semiconductor device layer;
forming a second semiconductor device in a second semiconductor device layer, the second semiconductor device formed with at least one second connector located at an interior surface of the second semiconductor device layer;
forming a via in the first semiconductor device layer, the via extending from the first surface of the first semiconductor device layer to an opposing second surface of the first semiconductor device layer, and the via at the second surface of the first semiconductor device layer corresponding to the location of the second connector of the second semiconductor device; and
joining the second surface of the first semiconductor device layer and the interior surface of the second semiconductor device layer, wherein the via at the second surface of the first semiconductor device layer is coupled to the second connector of the second semiconductor device.

2. The method of claim 1, wherein after the joining, the first semiconductor device and the second semiconductor device are vertically stacked with respect to each other.

3. The method of claim 1, wherein forming the via comprises:
deep reactive ion etching the first semiconductor device layer so that the via extends from the first surface of the first semiconductor device layer to the second surface of the first semiconductor device layer.

4. The method of claim 1, wherein prior to the joining, the method further comprises:
filling the via with a polysilicon fill, wherein the polysilicon fill is electrically coupleable to the second connector of the second semiconductor device.

5. The method of claim 1, wherein the via is a first via, and further comprising:
forming a second via in a semiconductor cover layer, the second via extending from an exterior surface of the semiconductor cover layer to an interior surface of the semiconductor cover layer, and the second via located at the interior surface of the semiconductor cover layer corresponding to the location of the first via at the first surface of the first semiconductor device layer; and
forming a third via in the semiconductor cover layer, the third via extending from the exterior surface of the semiconductor cover layer to the interior surface of the semiconductor cover layer, and the third via located at the interior surface of the semiconductor cover layer corresponding to the location of the first connector of the first semiconductor device.

6. The method of claim 5, wherein prior to the joining, the method further comprises:
filling the first via with a first polysilicon fill, wherein the first polysilicon fill is electrically coupleable to the second connector of the second semiconductor device; and
filling the second via with a second polysilicon fill, wherein the second polysilicon fill of the second via is electrically coupleable to the first polysilicon fill of the first via; and
filling the third via with a third polysilicon fill, wherein the third polysilicon fill of the third via is electrically coupleable to the first connector of the first semiconductor device.

7. The method of claim 6, further comprising:
joining the first surface of the first semiconductor device layer and the interior surface of the semiconductor cover layer,
wherein the second via at the interior surface of the semiconductor cover layer is electrically coupled to the first via at the first surface of the first semiconductor device layer, and
wherein the third via at the interior surface of the semiconductor cover layer is electrically coupled to the first connector of the first semiconductor device.

8. The method of claim 7, further comprising:
communicating a first signal between the first semiconductor device and the exterior surface of the semiconductor cover layer, the first signal communicated through the third via; and
communicating a second signal between the second semiconductor device and the exterior surface of the semiconductor cover layer, the second signal communicated through the first via and the second via.

9. The method of claim 1, wherein forming the first semiconductor device in the first semiconductor device layer comprises forming a first Micro-Electro-Mechanical Systems (MEMs) device, and wherein forming the second semiconductor device in the second semiconductor device layer comprises forming a second MEMs device.

10. The method of claim 9, wherein the first MEMs device is a first MEMs accelerometer, wherein the second MEMs device is a second MEMs accelerometer, and wherein joining the first semiconductor device layer and the second semiconductor device layer further comprises:
orienting the first MEMs accelerometer in a first direction to sense acceleration in the first direction; and
orienting the second MEMs accelerometer in a second direction to sense acceleration in the second direction, wherein the second direction is perpendicular to the first direction.

11. The method of claim 9, wherein the first MEMs device is a first MEMs gyroscope, wherein the second MEMs device is a second MEMs gyroscope, and wherein joining the first semiconductor device layer and the second semiconductor device layer further comprises:
orienting the first MEMs gyroscope in a first direction to sense rotation in the first direction; and
orienting the second MEMs gyroscope in a second direction to sense rotation in the second direction, wherein the second direction is perpendicular to the first direction.

12. A multi-chip semiconductor device assembly, comprising:
a first semiconductor device layer with a first surface and an opposing second surface;
a second semiconductor layer with an interior surface joined with the second surface of the first semiconductor device layer;
a semiconductor cover layer with an exterior surface and an interior surface, the interior surface of the semiconductor cover layer joined with the first surface of the first semiconductor device layer;
a first semiconductor device in the first semiconductor device layer;
a second semiconductor device in the second semiconductor device layer;
at least one first connector located at the first surface of the first semiconductor device layer and communicatively coupled to the first semiconductor device;
at least one second connector located at the interior surface of the second semiconductor device layer and communicatively coupled to the second semiconductor device; and
a first filled via in the first semiconductor device layer, the first filled via extending from the first surface of the first semiconductor device layer to the second surface of the first semiconductor device layer, and the first filled via at the second surface of the first semiconductor device layer corresponding to a location of the second connector of the second semiconductor device;
a second filled via in the semiconductor cover layer, the second filled via extending from the exterior surface of the semiconductor cover layer to the interior surface of the semiconductor cover layer, and the second filled via located at the interior surface of the semiconductor cover layer corresponding to a location of the first filled via at the first surface of the first semiconductor device layer; and
a third filled via in the semiconductor cover layer, the third filled via extending from the exterior surface of the semiconductor cover layer to the interior surface of the semiconductor cover layer, and the third filled via located at the interior surface of the semiconductor cover layer corresponding to a location of the first connector of the first semiconductor device,
wherein the first filled via, the second filled via, and the second connector are communicatively coupled, and
wherein the third filled via and the first connector are communicatively coupled.

13. The multi-chip semiconductor device assembly of claim 12, further comprising:
an electrically conductive fill in the first filled via, the second filled via and the third filled via.

14. The multi-chip semiconductor device assembly of claim 12, wherein the first semiconductor device and the second semiconductor device are vertically stacked with respect to each other.

15. The multi-chip semiconductor device assembly of claim 12, wherein the first semiconductor device is a first MEMs accelerometer, and wherein the second semiconductor device is a second MEMs accelerometer.

16. The multi-chip semiconductor device assembly of claim 12, wherein the first semiconductor device is a first MEMs gyroscope, and wherein the second semiconductor device is a second MEMs gyroscope.
